(19) United States
(12) Patent Application Publication
(10) Pub. No.: US 2006/0105532 A1
(43) Pub. Date: May 18, 2006

(54) Integrated circuit and method for manufacturing an integrated circuit on a chip

(75) Inventor: Christoph Bromberger, Heilbronn (DE)

Correspondence Address: BIRCH STEWART KOLASCH & BIRCH, PO BOX 747, FALLS CHURCH, VA, 22040-0747, US

(73) Assignee: ATMEL GERMANY GMBH

(21) Appl. No.: 11/272,702

(22) Filed: Nov. 15, 2005

(30) Foreign Application Priority Data
Nov. 16, 2004 (DE) DE 10 2004 055 18

(51) Int. Cl. H01L 21/331

(52) U.S. Cl. 438/312

(57) ABSTRACT

An integrated circuit and method for manufacturing an integrated circuit on a chip is provided, whereby a first bipolar transistor has a first collector region of a first conductivity type and a second bipolar transistor has a second collector region of the first conductivity type. The method includes the steps of growing the first collector region by a first collector epitaxy and subsequently a second collector epitaxy, and also growing the second collector region by the first collector epitaxy and the second collector epitaxy. Introducing into the first collector region, after the first collector epitaxy and before the second collector epitaxy, dopants of the first conductivity type in such a way that a first dopant concentration in a first epitaxial layer grown by the first collector epitaxy of the first collector region exceeds a second dopant concentration in a first epitaxial layer grown by the first collector epitaxy, of the second collection region.

This nonprovisional application claims priority under 35 U.S.C. § 119(a) on Patent Application No. DE 10 2004 055 183.9 filed in Germany on Nov. 16, 2004, which is herein incorporated by reference.

### BACKGROUND OF THE INVENTION

1. Field of the Invention

The present invention relates to an integrated circuit and a method for manufacturing an integrated circuit on a chip.

2. Description of the Background Art

Vertical bipolar transistors having a different dielectric strength and frequency capability are available in semiconductor technologies. In this respect, the dielectric strength usually increases with declining collector doping. Likewise, low collector doping leads to a lower cutoff frequency.

The method of the selectively implanted collector is known particularly in the high-frequency range. In this respect, a first and second semiconductor region are made from a uniform collector epitaxy; the collector of a first bipolar transistor having high dielectric strength and lower frequency capability is formed from the first semiconductor region, and the collector of a second bipolar transistor having a lower dielectric strength and better frequency capability is formed from the second semiconductor region. To that end, the second semiconductor region is provided in limited areas with additional collector implantation (SIC—selectively implanted collector). By means of this selective collector implantation, the dopant concentration in the second semiconductor region is increased above the dopant concentration in the first semiconductor region.

pn Junctions in semiconductors exist particularly as “long” or “short” diodes. In a “long” p-n-n⁺ diode, the space-charge zone ends at reverse voltages, as they are applied at the pn junction under normal operating conditions, on the n side in the n⁻ region, whereas in “short” diodes it punches through to the n⁺ region. Through the punching through, the blocking capability of “short” diodes is reduced compared with the blocking capability of a “long” diode at the same dopant level. For a bipolar transistor with a specific collector-base breakdown voltage, a certain expansion of the collector drift zone is therefore necessary and consequently requires a specific collector epitaxy thickness.

Conversely, particularly in the high-frequency range, the collector resistance is a major criterion for bipolar transistor quality. Part of the collector resistance is the resistance of a possible collector drift zone portion, not depleted under normal operating conditions. The expansion of the collector space-charge zone is generally reduced under the desired operating condition by a sufficiently high selective collector implantation. Because the requirements in the more highly blocking transistor must be considered in establishing the thickness of the collector epitaxy, the second semiconductor region is frequently not totally depleted during operation of the second bipolar transistor. As a result, the collector resistance of the second bipolar transistor is detrimentally increased. For example, an 120-nm undepleted collector drift zone with a conventional cross section of 20×0.6 μm² even at a high collector doping of 1e17 cm⁻³ still leads to an additional collector resistance of 8 Ω, which in many cases constitutes the major portion of the total collector resistance.

### SUMMARY OF THE INVENTION

It is therefore an object of the present invention to provide a method by which different transistors with different collector drift zones can be realized on a single chip.

Accordingly, a first bipolar transistor having a first collector region of a first conductivity type and a second bipolar transistor having a second collector region of the first conductivity type are made in a method for manufacturing an integrated circuit on a chip. The first conductivity type here, for example, is a n-conductivity type, as can be made, for example, by phosphorus doping.

For the manufacture, the first collector region is grown by a first collector epitaxy and a second collector epitaxy. In so doing, the first collector epitaxy and the second collector epitaxy are carried out at different times in order to perform at least one process step between these two epitaxies. The semiconductor material silicon is deposited, for example, for the first collector epitaxy and the second collector epitaxy. Furthermore, the second collector region is also grown by the first collector epitaxy and the second collector epitaxy preferably with the same semiconductor material.

In the first collector region, after the first collector epitaxy and before the second collector epitaxy, dopants of the first conductivity type are introduced in such a way that a first dopant concentration in a first epitaxial layer, grown by the first collector epitaxy, of the first collector region exceeds a second dopant concentration in a first epitaxial layer, grown by the first collector epitaxy, of the second collection region. In so doing, all employable dopants of the first conductivity type can be introduced preferably solely into the first collector region. To introduce the dopants, preferably, the dopants are implanted in the material of the first collector epitaxy in the first collector region, the second collector region being protected by a mask for this implantation step and therefore not being doped.

By means of the selective doping, hereby a high-doped, quasimetallic “support” is formed beneath the material of the second collector epitaxy of the first collector region. If after the second collector epitaxy, dopants are also introduced, especially implanted, into the material of the second collector epitaxy in the first collector region, a low-resistive connected, thin, and high-doped collector drift zone can be formed by these process steps.

To produce different dopant profiles and dopant gradients of the first conductivity type within the first collector region, in a further embodiment of the invention, a third collector epitaxy and optionally still further collector epitaxies may be provided, between which in each case one or more additional process steps, such as the implantation of dopants of the first conductivity type, are carried out.

According to another embodiment of the present invention, in the first collector region after the second collector epitaxy, dopants of the first conductivity type are introduced in such a way that a third dopant concentration in a second epitaxial layer, grown by the second collector epitaxy, of the first collector region exceeds a fourth dopant concentration in a second epitaxial layer, grown by the second collector epitaxy, of the second collector region.

A further embodiment provides that a first base region, adjacent to the first collector region, of a second conductivity type is applied with a silicon-germanium layer and/or a second base region, adjacent to the second collector region, of a second conductivity type is applied with a silicon-germanium layer.

It is especially preferred for the selective introduction of dopants for a mask, for example, of a photoresist or an oxide to be applied in a patterned manner and for the dopants to be implanted afterwards.

An especially advantageous development of the invention provides that the first collector epitaxy is a lateral solid phase epitaxy, wherein amorphous silicon is applied to a silicide layer and to a monocrystalline silicon substrate and in an annealing step is crystallized out proceeding from the monocrystalline silicon substrate that acts as a crystallization nucleus. In addition, for doping the material of the first collector epitaxy, the silicide layer may be provided with such a type of impurity that diffuses subsequently into the first collector region and there acts as a dopant of the first conductivity type.

Another embodiment of the invention provides for an integrated circuit on a chip. The integrated circuit having at least a first bipolar transistor and a second bipolar transistor. Moreover, the first bipolar transistor has a first collector region, grown by a first epitaxial layer and a second epitaxial layer, of a first conductivity type. The second bipolar transistor has a second collector region, grown by the first epitaxial layer and the second epitaxial layer, of the same first conductivity type.

This has the effect that the first collector region has a first collector drift zone and the second collector region, a second collector drift zone, which are substantially determined by the thickness and the dopant concentration in the collector region.

Compared with the second collector drift zone, the first collector drift zone is patterned by different dopant profiles in the collector regions of the first and second transistor. To that end, it is provided that the first epitaxial layer of the first collector region has a higher dopant concentration than the first epitaxial layer of the second collector region.

The second epitaxial layer of the first collector region, moreover, can have a higher dopant concentration than the second epitaxial layer of the second collector region. The total dopant concentration in the active collector of the first transistor can thus be greater than the dopant concentration in the active collector of the second transistor. Therefore, the first transistor is suitable preferably for high-frequency signals and the second transistor advantageously for an optimized dielectric strength.

An embodiment of this aspect of the invention provides that the first collector region is directly adjacent to a silicon-germanium layer of a first base region of a second conductivity type of the first bipolar transistor and/or the second collector region is directly adjacent to a silicon-germanium layer of a second base region of the second conductivity type of the second bipolar transistor.

According to a preferred embodiment, within the first collector region and/or within the second collector region, the first epitaxial layer is adjacent at least in part to a silicide layer, to enable a low-resistance connection of the epitaxial layer.

An aspect of the invention, different in turn, is an integrated cascode circuit having a first bipolar transistor and a second bipolar transistor. The first bipolar transistor has a first collector region, grown by a first epitaxial layer and a second epitaxial layer, of a first conductivity type. Similarly, the second bipolar transistor has a second collector region, grown by the first epitaxial layer and the second epitaxial layer, of the first conductivity type.

The first collector region can have a first collector drift zone and the second collector region, a second collector drift zone, whereby the first collector drift zone is shortened compared with the second collector drift zone due to different dopant profiles within the first epitaxial layer. To achieve cascode functionality, the first collector region of the first bipolar transistor is electrically connected to a second emitter region of the second bipolar transistor.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 is a schematic sectional drawing through a first bipolar transistor and through a second bipolar transistor according to an embodiment of the present invention;

FIG. 2a is a schematic of a dopant course along section line a; and

FIG. 2b is a schematic of a dopant course along section line b.

### DETAILED DESCRIPTION

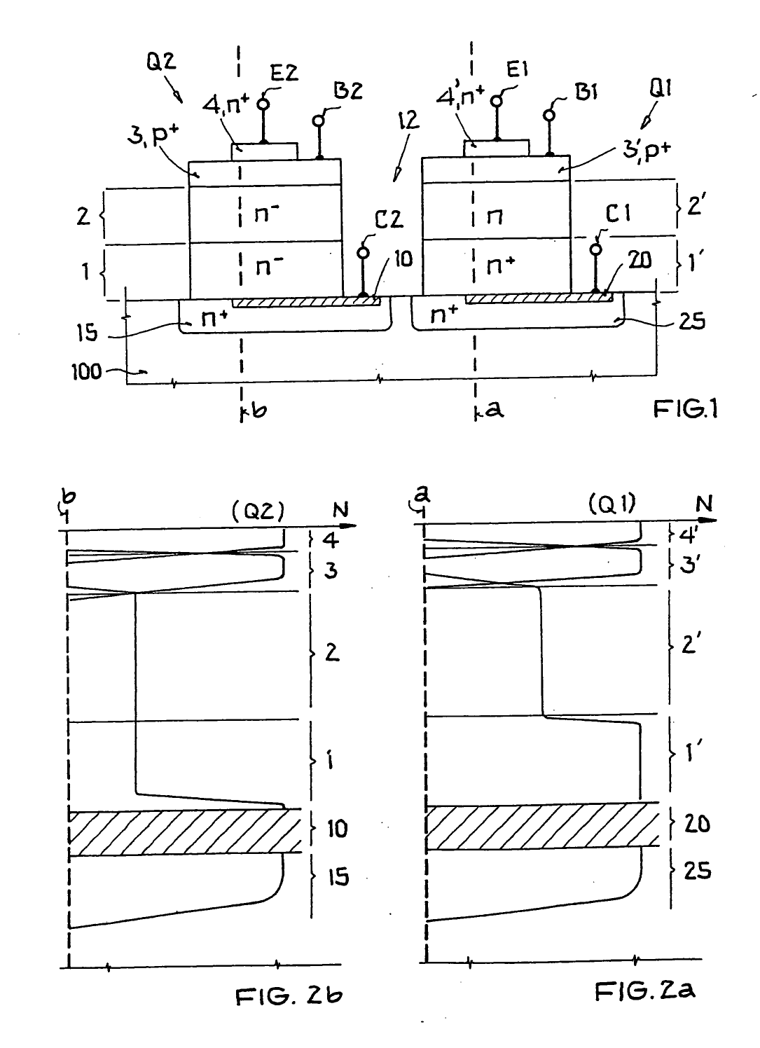

FIG. 1 shows two bipolar transistors Q1 and Q2. Both transistors Q1 and Q2 are described as npn bipolar transistors in the following text. The invention may be equally used for pnp bipolar transistors as well, however, by a simple exchange of conductivity types. The semiconductor regions 3′ and 4′ of the first, right bipolar transistor Q1 of FIG. 1 in this exemplary embodiment are each identical to the corresponding semiconductor regions 3, 4 of the second, left bipolar transistor Q2.

The first transistor Q1 is made by epitaxial methods on a substrate 100. To that end, for a low-resistance connection of the collector C1, a high-doped well 25 (8e19 cm⁻³) is introduced into the p-doped substrate and a silicide layer 20 is formed. Above the silicide layer 20, a first collector epitaxial layer 1′ is grown monocrystalline, for example, by solid phase epitaxy of a thickness of, for example, 70 nm. In the same epitaxy, moreover, collector epitaxial layer 1 (1e17 cm⁻³) of the second collector region (1, 2) of the second transistor Q2 is grown. This second collector region (1, 2) of second transistor Q2 is also grown monocrystalline on a silicide layer 10, whereby silicide layer 10 in turn is applied to a high n-doped well 15 (8e19 cm⁻³), introduced into substrate 100, for connecting collector C2 of second transistor Q2.

Furthermore, silicide layers 10, 20 act as solid dopant sources, with the aid of which during the subsequent course of the manufacturing process a dopant concentration preferably greater than 1e20 cm⁻³ is produced by outward diffusion in the edge regions of high-doped wells 15, 25 and collector epitaxial layers 1, 1′, which are adjacent to silicide layers 10, 20.

The first collector epitaxial layer 1 and/or 1′ is followed by a selective implantation of dopants of the first conductivity type in collector epitaxial layer 1′ of first collector region 1′, so that a dopant concentration of 1e19 cm⁻³ is introduced in the collector epitaxial layer 1′ of first collector region 1′ of first transistor Q1. Thereafter, a second collector epitaxial layer 2 and/or 2′ with a dopant concentration of 2e16 cm⁻³ is applied. This second collector epitaxial layer 2, 2′ in transistors Q1 and Q2 is adjacent to semiconductor region 3′, 3 (with a dopant concentration of, for example, 2e19 cm⁻³) of base B1 and/or B2 of the respective transistor Q1 and/or Q2. For example, the second collector epitaxial layer 2, 2′ has a thickness of 50 nm. By a selective implantation of dopants of the first conductivity type a higher dopant concentration is produced in the second collector epitaxial layer 2′ of first transistor Q1 compared with a lower dopant concentration in the second collector epitaxial layer 2 of second transistor Q2.

The base semiconductor region 3′, 3 here preferably has a silicon-germanium layer. In turn, semiconductor region 4′, 4 of emitter E1 and/or E2 of the respective transistor Q1 and/or Q2 is adjacent to the base semiconductor region 3′, 3. In this case, in this exemplary embodiment of the invention, first collector epitaxial layer 1 and/or 1′, second collector epitaxial layer 2 and/or 2′ and emitter layer 4 and/or 4′ are n-doped, whereas base layer 3, 3′ is p-doped.

The difference between transistors Q1 and Q2 is determined solely by the different dopant concentrations in collector epitaxial layers 1 and 1′, as well as 2 and 2′. This is explained below using the dopant profiles formed by the dopant courses N(Q1) and N(Q2) along sections a and b. Here, section a runs through the first bipolar transistor Q1, shown in FIG. 2a, and section b through the second bipolar transistor Q2, shown in FIG. 2b.

FIG. 2a shows that the first collector epitaxial layer 1′ of the first transistor Q1 is high n⁺-doped and enables a quasimetallic connection of the second collector epitaxial layer 2′. In contrast to the first collector epitaxial layer 1′ of the first transistor Q1, the first collector epitaxial layer 1 of the second transistor Q2 is low n⁻-doped, so that the collector drift zone of the second transistor Q2 extends substantially over the thickness of the first collector epitaxial layer 1 and second collector epitaxial layer 2.

For higher doping of the first collector epitaxial layer 1′ of the first transistor Q1, compared with the first collector epitaxial layer 1 of the second transistor Q2, a mask is provided in the manufacturing process, which enables a selective implantation of dopants in the first collector epitaxial layer 1′ of the first transistor Q1 and prevents doping of the first collector epitaxial layer 1 of the second transistor Q2.

Furthermore, the second collector epitaxial layer 2′ (5e17 cm⁻³) of the first transistor Q1 is also significantly higher doped than that of the second transistor Q2, to improve the high-frequency properties of the first transistor Q1 compared with the second transistor Q2.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A method for manufacturing an integrated circuit on a chip, the integrated circuit including a first bipolar transistor having a first collector region of a first conductivity type and a second bipolar transistor having a second collector region of the first conductivity type, the method comprising the steps of:
growing the first collector region by a first collector epitaxy and subsequently a second collector epitaxy;
growing the second collector region by the first collector epitaxy and the second collector epitaxy; and
selectively introducing into the first collector region, after the first collector epitaxy and before the second collector epitaxy, dopants of the first conductivity type in such a way that a first dopant concentration in a first epitaxial layer grown by the first collector epitaxy of the first collector region is greater than a second dopant concentration in a first epitaxial layer grown by the first collector epitaxy of the second collection region.

2. The method according to claim 1, wherein, in the first collector region after the second collector epitaxy, dopants of the first conductivity type are introduced in such a way that a third dopant concentration in a second epitaxial layer grown by the second collector epitaxy of the first collector region is greater than a fourth dopant concentration in a second epitaxial layer grown by the second collector epitaxy of the second collector region.

3. The method according to claim 1, wherein a first base region adjacent to the first collector region of a second conductivity type is applied with a silicon-germanium layer and/or a second base region adjacent to the second collector region of a second conductivity type is applied with a silicon-germanium layer.

4. The method according to claim 1, wherein for the selective introduction of the dopant, a mask is applied and the dopants are implanted.

5. The method according to claim 1, wherein the first collector epitaxy is a lateral solid phase epitaxy, wherein amorphous silicon is applied to a silicide layer and to a monocrystalline silicon substrate and in an annealing step is crystallized out proceeding from the monocrystalline silicon substrate that acts as a crystallization nucleus.

6. An integrated circuit on a chip, the integrated circuit comprising:
a first bipolar transistor having a first collector region grown by a first epitaxial layer and a second epitaxial layer of a first conductivity type; and
a second bipolar transistor having a second collector region grown by the first epitaxial layer and the second epitaxial layer of the said first conductivity type, the first collector region having a first collector drift zone and the second collector region having a second collector drift zone, the first collector drift zone being shortened in comparison with the second collector drift zone in that the first epitaxial layer of the first collector region has a higher dopant concentration than the first epitaxial layer of the second collector region.

7. The integrated circuit according to claim 6, wherein the second epitaxial layer of the first collector region has a higher dopant concentration than the second epitaxial layer of the second collector region.

8. The integrated circuit according to claim 6, wherein the first collector region is directly adjacent to a silicon-germanium layer of a first base region of a second conductivity type of the first bipolar transistor and/or the second collector region is directly adjacent to a silicon-germanium layer of a second base region of the second conductivity type of the second bipolar transistor.

9. The integrated circuit according to claim 6, wherein, within the first collector region and/or within the second collector region, the first epitaxial layer is at least partly adjacent to a silicide layer.

10. An integrated cascode circuit comprising:
a first bipolar transistor having a first collector region grown by a first epitaxial layer and a second epitaxial layer of a first conductivity type; and
a second bipolar transistor having a second collector region grown by the first epitaxial layer and the second epitaxial layer of the said first conductivity type, the first collector region having a first collector drift zone and the second collector region having a second collector drift zone, the first collector drift zone being shortened in comparison with the second collector drift zone in that the first epitaxial layer of the first collector region has a higher dopant concentration than the first epitaxial layer of the second collector region, and the first collector region of the first bipolar transistor being electrically connected to a second emitter region of the second bipolar transistor.

11. The integrated cascode circuit according to claim 10, wherein the second epitaxial layer of the first collector region has a higher dopant concentration than the second epitaxial layer of the second collector region.
